(19) United States
(12) Patent Application Publication
(10) Pub. No.: US 2025/0142810 A1
(43) Pub. Date: May 1, 2025

(54) SEMICONDUCTOR MEMORY DEVICE

(71) Applicant: Samsung Electronics Co., Ltd., Suwon-si (KR)

(72) Inventors: TAEJIN KIM, Suwon-si (KR); HYUNGEUN CHOI, Suwon-si (KR); TAEJIN PARK, Suwon-si (KR); EUIJOONG SHIN, Suwon-si (KR); SANGHO LEE, Suwon-si (KR)

(21) Appl. No.: 18/675,285

(22) Filed: May 28, 2024

(30) Foreign Application Priority Data
Oct. 26, 2023 (KR) 10-2023-0145090

(51) Int. Cl. H10B 12/00; H01L 23/522; H01L 23/528

(52) U.S. Cl. CPC H10B 12/482; H01L 23/5226; H01L 23/5283; H10B 12/488; H10B 12/50

(57) ABSTRACT

A semiconductor memory device includes a bit line extending above a substrate in a second horizontal direction, first and second active patterns beneath the bit line, each of the first and second active patterns having a first surface in contact with the bit line without a dopant source layer therebetween and a second surface opposite to the first surface in a vertical direction, a back-gate electrode between the first and second active patterns and extending above the substrate in a first horizontal direction by crossing the bit line, a first word line extending in the first horizontal direction at one side of the first active pattern, a second word line extending in the first horizontal direction at an opposite side of the second active pattern, and contact patterns in contact with the second surfaces of the first and second active patterns.

### REFERENCE TO RELATED APPLICATIONS

This application is based on and claims priority under 35 U.S.C. § 119 to Korean Patent Application No. 10-2023-0145090, filed on Oct. 26, 2023, in the Korean Intellectual Property Office, the disclosure of which is incorporated by reference herein in its entirety.

### BACKGROUND OF THE INVENTION

The inventive concept relates to a semiconductor memory device, and more particularly, to a semiconductor memory device including a vertical channel transistor.

It may be difficult to improve the integration of a semiconductor memory device having a two-dimensional transistor or a planar transistor by reducing an area occupied by a memory cell. Accordingly, a semiconductor memory device having a three-dimensional transistor or a vertical channel transistor is proposed. In semiconductor memory devices having a vertical channel transistor, it may be beneficial to impede/prevent the characteristic degradation of a capacitor or a transistor in a peripheral circuit structure.

### SUMMARY OF THE INVENTION

The inventive concept provides a semiconductor memory device which includes a vertical channel transistor capable of improving the integration of the semiconductor memory device and may also impede/prevent the characteristic degradation of a capacitor or a transistor in a peripheral circuit structure.

According to an aspect of the inventive concept, there is provided a semiconductor memory device including a bit line extending above a substrate in a second horizontal direction, first and second active patterns beneath the bit line, each of the first and second active patterns having a first surface in contact with the bit line without a dopant source layer therebetween and a second surface opposite to the first surface in a vertical direction that is perpendicular to the substrate, a back-gate electrode between the first and second active patterns and extending above the substrate in a first horizontal direction that is perpendicular to the second horizontal direction by crossing the bit line, a first word line extending in the first horizontal direction at one side of the first active pattern, a second word line extending in the first horizontal direction at an opposite side of the second active pattern, and contact patterns in contact with the second surfaces of the first and second active patterns. The first and second active patterns may include first source/drain regions adjacent to the bit line, second source/drain regions adjacent to the contact patterns, and channel regions between the first source/drain regions and the second source/drain regions.

According to another aspect of the inventive concept, there is provided a semiconductor memory device including a bit line extending above a substrate in a second horizontal direction, first and second active patterns alternating with each other in the second horizontal direction beneath the bit line, each of the first and second active patterns having a first surface in contact with the bit line without a dopant source layer therebetween and a second surface opposite to the first surface in a vertical direction that is perpendicular to the substrate, a back-gate electrode between the first and second active patterns and extending above the substrate in a first horizontal direction that is perpendicular to the second horizontal direction by crossing the bit line, a first word line extending in the first horizontal direction at one side of the first active pattern, a second word line extending in the first horizontal direction at an opposite side of the second active pattern, gate insulating patterns between the first and second active patterns and the first and second word lines, and contact patterns in contact with the second surfaces of the first and second active patterns without a dopant source layer therebetween.

The first and second active patterns may include first source/drain regions adjacent to the bit line, second source/drain regions adjacent to the contact patterns, and channel regions between the first source/drain regions and the second source/drain regions.

According to another aspect of the inventive concept, there is provided a semiconductor memory device including a cell array structure on a first substrate and a peripheral circuit structure bonded to the cell array structure. The cell array structure may include a capacitor on the first substrate, a vertical channel transistor above the capacitor and electrically connected to the capacitor through contact patterns, and a first wiring structure above the vertical channel transistor and electrically connected to the vertical channel transistor through a bit line.

The vertical channel transistor may include active patterns located above the first substrate in a vertical direction and separated from each other in a first horizontal direction and a second horizontal direction and first source/drain regions and second source/drain regions on and beneath the active patterns, respectively, the first source/drain regions being in contact with and electrically connected to the bit line without a dopant source layer therebetween, and the second source/drain regions being electrically connected to the capacitor through the contact patterns in contact with the second source/drain regions without a dopant source layer therebetween. The peripheral circuit structure may include a peripheral circuit transistor beneath a second substrate and a second wiring structure beneath the peripheral circuit transistor and bonded to the first wiring structure.

### BRIEF DESCRIPTION OF THE DRAWINGS

Embodiments of the inventive concept will be more clearly understood from the following detailed description taken in conjunction with the accompanying drawings in which:

FIG. 1 is a layout diagram of a semiconductor memory device according to an embodiment;

FIGS. 2 and 3 are partial cross-sectional views of a semiconductor memory device according to embodiments and are cross-sectional views taken along line A-A′ of FIG. 1;

FIGS. 4 to 7 are cross-sectional views for describing a method of manufacturing a semiconductor wafer, according to an embodiment;

FIG. 8 is a cross-sectional view for describing a method of manufacturing a semiconductor wafer, according to an embodiment;

FIGS. 9 to 13 are cross-sectional views for describing a method of manufacturing a semiconductor wafer, according to an embodiment;

FIG. 14 is a cross-sectional view for describing a method of manufacturing a semiconductor wafer, according to an embodiment;

FIG. 15 is a cross-sectional view of a semiconductor memory device according to an embodiment; and

FIGS. 16 to 24 are cross-sectional views for describing a method of manufacturing the semiconductor memory device of FIG. 15.

### DETAILED DESCRIPTION

Hereinafter, embodiments of the inventive concept are described in detail with reference to the accompanying drawings. The embodiments below may be implemented individually or in combination. Therefore, the technical idea of the inventive concept is not interpreted by being limited to a single embodiment. In the embodiments, an order of first, second, and nth is only to facilitate a description, and the inventive concept is not limited to the order.

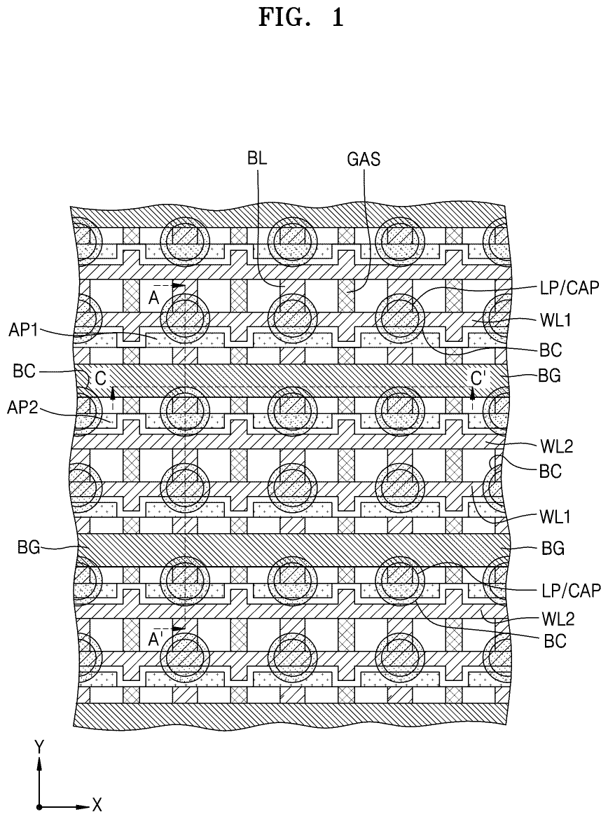

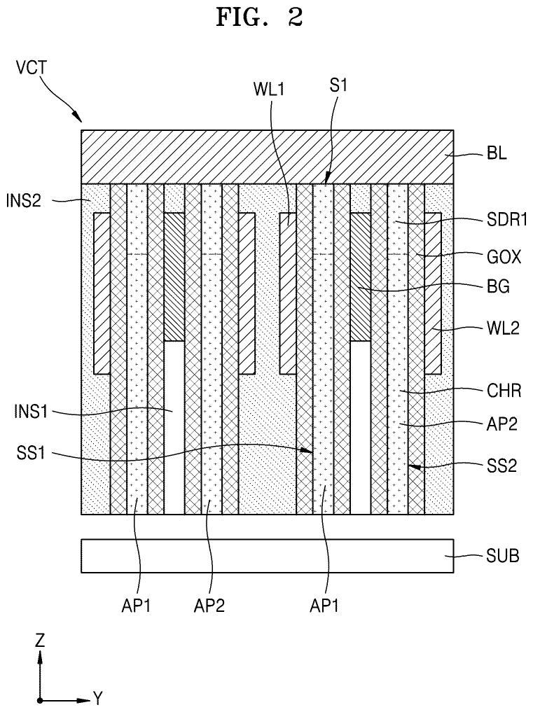

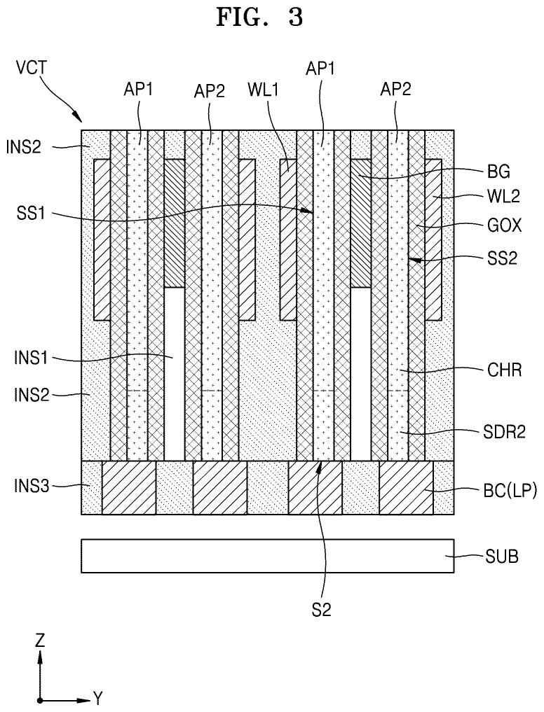

FIG. 1 is a layout diagram of a semiconductor memory device according to an embodiment, and FIGS. 2 and 3 are partial cross-sectional views of the semiconductor memory device according to embodiments and are cross-sectional views taken along line A-A′ of FIG. 1.

Particularly, the semiconductor memory device according to embodiments may include memory cells each including a vertical channel transistor VCT. FIG. 2 shows that a bit line BL is on the top, and FIG. 3 shows that contact patterns BC are on the bottom. In FIG. 3, the contact patterns BC may be landing pads LP electrically connected to a capacitor CAP.

Bit lines BL may be arranged above a substrate SUB and separated from each other in a first horizontal direction (the X direction). The bit lines BL may extend in parallel in a second horizontal direction (the Y direction) that intersects the first horizontal direction (the X direction) in which the bit lines BL are parallel to each other. The substrate SUB may include a material (e.g., a silicon wafer) having a semiconductor characteristic.

The bit lines BL may be constructed as a single layer or double layers. The bit lines BL may include a metal pattern. The metal pattern constituting the bit lines BL may include conductive metal nitride (e.g., titanium nitride, tantalum nitride, or the like) or a metal (e.g., tungsten, titanium, tantalum, or the like). The metal pattern constituting the bit lines BL may include metal silicide, such as titanium silicide, cobalt silicide, or nickel silicide.

In some embodiments, the semiconductor memory device may include gap structures GAS between the bit lines BL. The gap structures GAS may extend in the second horizontal direction (the Y direction) and be parallel to each other in the first horizontal direction (the X direction). According to some embodiments, the gap structures GAS may be made of a conductive material and include an air gap or a void therein. As another example, the gap structures GAS may be air gaps surrounded by insulating layers. The gap structures GAS may reduce coupling noise of adjacent bit lines BL.

First and second active patterns AP1 and AP2 may be alternately arranged (i.e., may alternate with each other) in the second horizontal direction (the Y direction). The first active patterns AP1 may be separated from each other by a certain interval in the first horizontal direction (the X direction). The second active patterns AP2 may be separated from each other by a certain interval in the first horizontal direction (the X direction). In other words, the first and second active patterns AP1 and AP2 may be two-dimensionally arranged in the first horizontal direction (the X direction) and the second horizontal direction (the Y direction).

In some embodiments, the first and second active patterns AP1 and AP2 may include a monocrystalline semiconductor material. In some embodiments, the first and second active patterns AP1 and AP2 may include monocrystalline silicon. Each of the first and second active patterns AP1 and AP2 may have a length (or “width”) in the first horizontal direction (the X direction), a width in the second horizontal direction (the Y direction), and a height in a direction that is perpendicular to the first horizontal direction (the X direction) and the second horizontal direction (the Y direction).

Each of the first and second active patterns AP1 and AP2 may have a uniform width in the second horizontal direction (the Y direction). Each of the first and second active patterns AP1 and AP2 may have substantially the same width in the second horizontal direction (the Y direction). The widths of the first and second active patterns AP1 and AP2 may be several nanometers (nm) to tens of nm. For example, the widths of the first and second active patterns AP1 and AP2 may be 1 nm to 30 nm, more preferably, 1 nm to 10 nm. The length of each of the first and second active patterns AP1 and AP2 may be greater than the line width of the bit line BL.

Each of the first and second active patterns AP1 and AP2 may have a first surface S1 and a second surface S2 opposite to each other in a third direction (the Z direction, the vertical direction) that is perpendicular to the first horizontal direction (the X direction) and the second horizontal direction (the Y direction).

In some embodiments, the first surfaces S1 of the first and second active patterns AP1 and AP2 may be in contact with the bit line BL. In particular, the first surfaces S1 of the first and second active patterns AP1 and AP2 may be in contact with a metal pattern constituting the bit line BL without being in contact with a dopant source layer (e.g., an impurity-doped polysilicon pattern). In other words, the bit line BL may not include a dopant source layer and may include a single-layer or double-layer metal pattern. As used herein, the term “contact” refers to direct, physical contact.

In some embodiments, the second surfaces S2 of the first and second active patterns AP1 and AP2 may be in contact with the contact patterns BC. The contact patterns BC adjacent to each other may be separated from each other by third insulating patterns INS3. The contact patterns BC may include a metal pattern.

The metal pattern constituting the contact patterns BC may include conductive metal nitride (e.g., titanium nitride, tantalum nitride, or the like) or a metal (e.g., tungsten, titanium, tantalum, or the like). The metal pattern constituting the contact patterns BC may include metal silicide, such as titanium silicide, cobalt silicide, or nickel silicide. The second surfaces S2 of the first and second active patterns AP1 and AP2 may be in contact with the metal pattern constituting a contact pattern BC without being in contact with a dopant source layer (e.g., an impurity-doped polysilicon pattern). In other words, the contact pattern BC does not include a dopant source layer. The contact pattern BC may include a single-layer or double-layer metal pattern. Moreover, each contact pattern BC may be wider (e.g., at least twice as wide) in the second horizontal direction (the Y direction) than each of the second surfaces S2 of the first and second active patterns AP1 and AP2.

Each of the first and second active patterns AP1 and AP2 may have a first side surface SS1 and a second side surface SS2 opposite to each other in the second horizontal direction (the Y direction). The first side surface SS1 of a first active pattern AP1 may be adjacent to a first word line WL1, and the second side surface SS2 of a second active pattern AP2 may be adjacent to a second word line WL2.

Each of the first and second active patterns AP1 and AP2 may include a first source/drain region SDR1 adjacent to (e.g., in contact with) the bit line BL, a second source/drain region SDR2 adjacent to (e.g., in contact with) the contact pattern BC, and a channel region CHR between the first and second source/drain regions SDR1 and SDR2. The first source/drain region SDR1 may be a first dopant region. The second source/drain region SDR2 may be a second dopant region.

The first source/drain region SDR1 and the second source/drain region SDR2 may be a junction region. The first source/drain region SDR1 and the second source/drain region SDR2 may have a constant (or uniform) doping concentration in the vertical direction (the Z direction) that is perpendicular to the substrate SUB. In other words, the doping concentration of the first source/drain region SDR1 and the second source/drain region SDR2 may be constant (or uniform) without changing in the vertical direction (the Z direction) that is perpendicular to the substrate SUB.

The first and second source/drain regions SDR1 and SDR2 are dopant-doped regions in the first and second active patterns AP1 and AP2, and a dopant concentration in the first and second active patterns AP1 and AP2 may be greater than a dopant concentration in the channel region CHR. The first source/drain region SDR1 may be a drain region, and the second source/drain region SDR2 may be a source region.

The channel regions CHR of the first and second active patterns AP1 and AP2 may be controlled by the first and second word lines WL1 and WL2 and back-gate electrodes BG during an operation of the semiconductor memory device. The first and second word lines WL1 and WL2 and the back-gate electrodes BG may be commonly-named gate electrodes. Because the first and second active patterns AP1 and AP2 include a monocrystalline semiconductor material, a leakage current characteristic during an operation of the semiconductor memory device may be improved.

The back-gate electrodes BG may be above (or below) the bit lines BL to be separated from each other by a certain interval in the second horizontal direction (the Y direction). The back-gate electrodes BG may extend in the first horizontal direction (the X direction) by crossing the bit lines BL.

The back-gate electrodes BG may be between the first and second active patterns AP1 and AP2 adjacent to each other in the second horizontal direction (the Y direction), respectively. In other words, the first active pattern AP1 may be at one side of each of the back-gate electrodes BG and the second active pattern AP2 may be at the other (i.e., opposite) side of the back-gate electrode BG. The back-gate electrodes BG may have a height less than the height of the first and second active patterns AP1 and AP2 in the vertical direction (the Z direction).

A back-gate electrode BG may have a first surface (an upper surface) close to the bit line BL and a second surface (a lower surface) close to the contact pattern BC. The lower surfaces of the first and second word lines WL1 and WL2 may be at a different level from the level of the lower surface of the back-gate electrode BG. The first and second surfaces of the back-gate electrode BG may be vertically separated from the first and second surfaces S1 and S2 of the first and second active patterns AP1 and AP2.

The back-gate electrodes BG may include, for example, doped polysilicon, conductive metal nitride (e.g., titanium nitride, tantalum nitride, or the like), a metal (e.g., tungsten, titanium, tantalum, or the like), conductive metal silicide, conductive metal oxide, or a combination thereof.

During an operation of the semiconductor memory device, a negative voltage may be applied to the back-gate electrodes BG, thereby increasing the threshold voltage of the vertical channel transistor VCT. That is, the degradation of a leakage current characteristic due to a decrease in the threshold voltage along with the miniaturization of the vertical channel transistor VCT may be impeded/prevented.

A first insulating pattern INS1 may be between the first and second active patterns AP1 and AP2 adjacent to each other in the second horizontal direction (the Y direction). The first insulating pattern INS1 may be between the second source/drain regions SDR2 of the first and second active patterns AP1 and AP2.

The first insulating pattern INS1 may extend in the third direction (the Z direction) to be parallel to the back-gate electrodes BG. The distance between the second surface S2 of each of the first and second active patterns AP1 and AP2 and the back-gate electrode BG may vary according to the thickness of the first insulating pattern INS1. In some embodiments, the first insulating pattern INS1 may include a silicon oxide layer. In some embodiments, the first insulating pattern INS1 may include a silicon oxide layer or a silicon nitride layer.

The first and second word lines WL1 and WL2 may extend in the first horizontal direction (the X direction) and be alternately arranged in the second horizontal direction (the Y direction). The first word line WL1 may be at one side of the first active pattern AP1, and the second word line WL2 may be at the other (i.e., opposite) side of the second active pattern AP2. The first and second word lines WL1 and WL2 may be separated from the bit lines BL and the contact patterns BC in the vertical direction (the Z direction). In other words, the first and second word lines WL1 and WL2 may be between the bit lines BL and the contact patterns BC in a top view.

The first and second word lines WL1 and WL2 have a width in the second horizontal direction (the Y direction), wherein the width may vary on each bit line BL and on each gap structure GAS. Portions of the first word lines WL1 may be between first active patterns AP1 adjacent in the first horizontal direction (the X direction), and portions of the second word lines WL2 may be between second active patterns AP2 adjacent in the first horizontal direction (the X direction).

The first and second word lines WL1 and WL2 may include, for example, doped polysilicon, a metal, conductive metal nitride, conductive metal silicide, conductive metal oxide, or a combination thereof. First and second word lines WL1 and WL2 adjacent to each other may have sidewalls facing each other. Each of the first and second word lines WL1 and WL2 may have a first surface close to the bit line BL and a second surface close to the contact pattern BC.

In some embodiments, the first and second word lines WL1 and WL2 and the back-gate electrodes BG may have different heights (or lengths) in the vertical direction (the Z direction). For example, the back-gate electrodes BG may have a height greater than the height of the first and second word lines WL1 and WL2 in the vertical direction (the Z direction). In some embodiments, unlike FIGS. 2 and 3, the first and second word lines WL1 and WL2 and the back-gate electrodes BG may have the same height (or length) in the vertical direction (the Z direction).

Gate insulating patterns GOX may be between the first and second word lines WL1 and WL2 and the first and second active patterns AP1 and AP2. The gate insulating patterns GOX may extend in the first horizontal direction (the X direction) to be parallel to the first and second word lines WL1 and WL2. The gate insulating patterns GOX may be between the back-gate electrodes BG and the first and second active patterns AP1 and AP2. The gate insulating patterns GOX may extend in the first horizontal direction (the X direction) to be parallel to the back-gate electrodes BG.

A gate insulating pattern GOX may include a silicon oxide layer, a silicon oxynitride layer, a high dielectric layer having a higher dielectric constant than the silicon oxide layer, or a combination thereof. The high dielectric layer may include metal oxide or metal oxynitride. For example, the high dielectric layer usable as a gate insulating layer may include hafnium dioxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO₂), alumina (Al₂O₃), or a combination thereof but is not limited thereto.

A second insulating pattern INS2 may be between the first and second word lines WL1 and WL2 and between the gate insulating patterns GOX in the second horizontal direction (the Y direction). The second insulating pattern INS2 may extend in the first horizontal direction (the X direction) between the first and second word lines WL1 and WL2 and between the gate insulating patterns GOX.

The second insulating pattern INS2 may include a different material from that of the first insulating pattern INS1. In some embodiments, the second insulating pattern INS2 may include a silicon nitride layer. In some embodiments, the second insulating pattern INS2 may include a silicon oxide layer or a silicon oxynitride layer.

The landing pads LP may be on the contact patterns BC. Each of the landing pads LP may have various shapes, such as a circle, an oval, a rectangle, a square, a lozenge, and a hexagon, in a plan view. In some embodiments, when the contact patterns BC are omitted, only the landing pads LP may exist. The landing pads LP may include a metal pattern without including a dopant source layer.

The metal pattern constituting the landing pads LP may include conductive metal nitride (e.g., titanium nitride, tantalum nitride, or the like) or a metal (e.g., tungsten, titanium, tantalum, or the like). The metal pattern constituting the landing pads LP may include metal silicide, such as titanium silicide, cobalt silicide, or nickel silicide.

Capacitors CAP may be on the landing pads LP, respectively. The capacitors CAP may be electrically connected to the first and second active patterns AP1 and AP2, respectively. The capacitors CAP may be arranged in a matrix form in the first horizontal direction (the X direction) and the second horizontal direction (the Y direction). The capacitors CAP may fully or partially overlap the landing pads LP. The capacitors CAP may be fully or partially in contact with the upper surfaces of the landing pads LP.

According to an embodiment, the capacitors CAP may include a capacitor dielectric layer between storage electrodes and a plate electrode. In this case, a storage electrode may be in contact with a landing pad LP and have various shapes, such as a circle, an oval, a rectangle, a square, a lozenge, and a hexagon, in a plan view.

As described above, in the semiconductor memory device according to the inventive concept, the first surfaces S1 of the first and second active patterns AP1 and AP2 may be in contact with the metal pattern constituting the bit line BL without being in contact with a dopant source layer (e.g., an impurity-doped polysilicon pattern).

In the semiconductor memory device according to the inventive concept, the second surfaces S2 of the first and second active patterns AP1 and AP2 may be in contact with the metal pattern constituting the contact patterns BC without being in contact with a dopant source layer (e.g., an impurity-doped polysilicon pattern). In some embodiments, unlike FIG. 3, the contact patterns BC may include a dopant source layer (e.g., an impurity-doped polysilicon pattern).

As described below, in the semiconductor memory device according to the inventive concept, the first source/drain region SDR1 or both the first and second source/drain regions SDR1 and SDR2 is or are previously formed, and thus, it may be unlikely/prevented that capacitors or transistors in a peripheral circuit structure are affected by a high-temperature thermal process.

Accordingly, the semiconductor memory device according to the inventive concept may include the vertical channel transistor VCT capable of improving the integration of the semiconductor memory device and also impede/prevent the degradation of the capacitors CAP or a transistor in a peripheral circuit structure.

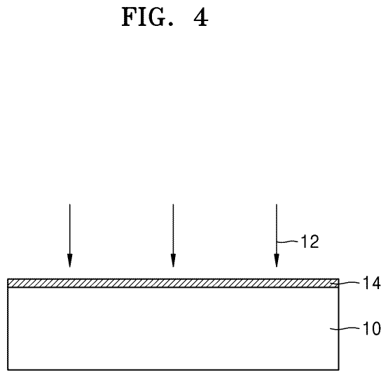

FIGS. 4 to 7 are cross-sectional views for describing a method of manufacturing a semiconductor wafer, according to an embodiment.

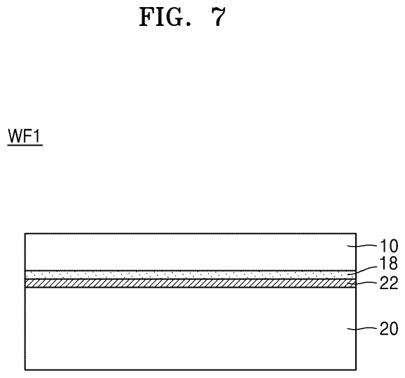

Particularly, FIGS. 4 to 7 correspond to a method of manufacturing a first semiconductor wafer WF1 (see FIG. 7) used to manufacture the semiconductor memory device of FIGS. 1 to 3. Referring to FIG. 4, an impurity ion injection region 14 is formed by injecting impurity ions 12 into a first substrate 10. The first substrate 10 may be a silicon substrate.

In some embodiments, if the first substrate 10 is a first conductive-type (e.g., P-type) silicon substrate, the impurity ions 12 may be second conductive-type (e.g., N-type) impurities, e.g., arsenide (As) or phosphorus (P) ions. In some embodiments, if the first substrate 10 is a second conductive-type (e.g., N-type) silicon substrate, the impurity ions 12 may be first conductive-type (e.g., P-type) impurities, e.g., boron (B) ions.

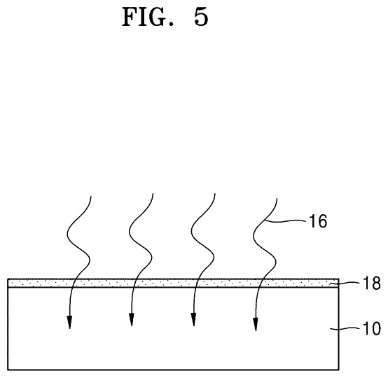

Referring to FIG. 5, heat 16 is applied to the first substrate 10 with the impurity ion injection region 14 (see FIG. 4) formed therein to activate the impurity ions included in the impurity ion injection region 14 (see FIG. 4). A thermal process of applying the heat 16 to the first substrate 10 may be performed at a high temperature of about 1000° C.

Through this thermal process, a first impurity region 18 with activated impurity ions may be formed on the first substrate 10. The first impurity region 18 may be an impurity region of a conductive type opposite to the conductive type of the first substrate 10. The first impurity region 18 may have a constant doping concentration of impurities in a direction that is perpendicular to the surface of the first substrate 10.

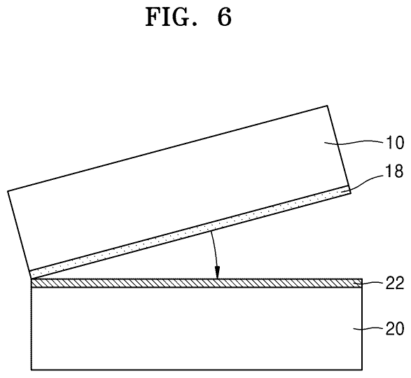

Referring to FIG. 6, a second substrate 20 having a first bonding insulating layer 22 formed thereon is prepared. The second substrate 20 may be a silicon substrate. The first bonding insulating layer 22 may include a silicon oxide layer or a silicon nitride layer.

Thereafter, the first substrate 10 having the first impurity region 18 formed thereon is bonded to the second substrate 20 having the first bonding insulating layer 22 formed thereon. The first substrate 10 is thermally bonded to the second substrate 20 by applying heat in a state in which the first impurity region 18 of the first substrate 10 is in contact with the first bonding insulating layer 22 of the second substrate 20. The first impurity region 18 of the first substrate 10 may be bonded to the first bonding insulating layer 22 of the second substrate 20 by a thermal process.

Referring to FIG. 7, by the bonding process of FIG. 6, the first semiconductor wafer WF1 having the first bonding insulating layer 22, the first impurity region 18, and the first substrate 10 formed on the second substrate 20 may be manufactured. The vertical channel transistor VCT to be described below may be manufactured on the first semiconductor wafer WF1 having the first impurity region 18, i.e., the first substrate 10 having the first impurity region 18 formed therebeneath.

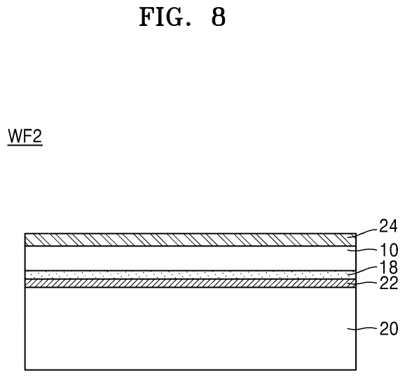

FIG. 8 is a cross-sectional view for describing a method of manufacturing a semiconductor wafer, according to an embodiment.

Particularly, FIG. 8 corresponds to a method of manufacturing a second semiconductor wafer WF2 used to manufacture the semiconductor memory device of FIGS. 1 to 3. The manufacturing process of FIGS. 4 to 7 is performed. Then, the first bonding insulating layer 22, the first impurity region 18, and the first substrate 10 may be formed on the second substrate 20.

Thereafter, a second impurity region 24 is formed on the first substrate 10. The second impurity region 24 may be formed by injecting impurity ions into the first substrate 10 and activating the injected impurity ions like FIGS. 4 and 5. The second impurity region 24 may be an impurity region of a conductive type opposite to the conductive type of the first substrate 10. The second impurity region 24 may have a constant doping concentration of impurities in a direction that is perpendicular to the surface of the first substrate 10. The vertical channel transistor VCT may be manufactured on this second semiconductor wafer WF2 having the first impurity region 18 and the second impurity region 24.

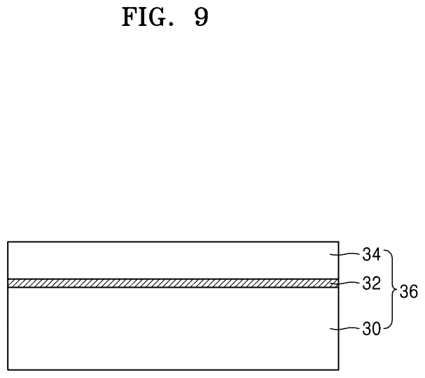

FIGS. 9 to 13 are cross-sectional views for describing a method of manufacturing a semiconductor wafer, according to an embodiment.

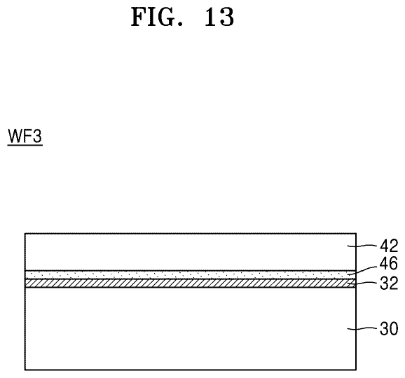

Particularly, FIGS. 9 to 13 correspond to a method of manufacturing a third semiconductor wafer WF3 (see FIG. 13) used to manufacture the semiconductor memory device of FIGS. 1 to 3. Referring to FIG. 9, a silicon on insulator (SOI) substrate 36 is prepared. The SOI substrate 36 may include a first silicon layer 30, an insulating layer 32, and a second silicon layer 34.

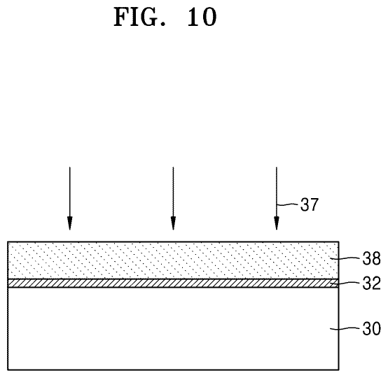

Referring to FIG. 10, an impurity ion injection region 38 is formed by injecting first impurity ions 37 into the second silicon layer 34 (see FIG. 9). In some embodiments, if the second silicon layer 34 (see FIG. 9) is a first conductive-type (e.g., P-type) silicon layer, the first impurity ions 37 may be second conductive-type (e.g., N-type) impurities, e.g., As or P ions. In some embodiments, if the second silicon layer 34 (see FIG. 9) is a second conductive-type (e.g., N-type) silicon layer, the first impurity ions 37 may be first conductive-type (e.g., P-type) impurities, e.g., B ions.

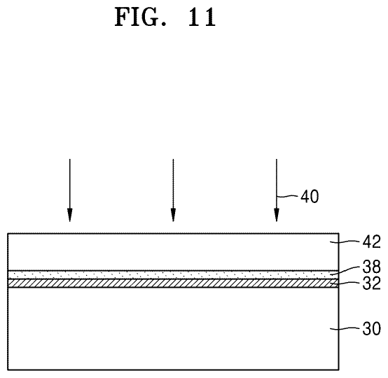

Referring to FIG. 11, a second silicon layer 42 of a recovered impurity type is formed by injecting second impurity ions 40 of a conductive type opposite to the conductive type of the first impurity ions 37 (see FIG. 10) into the impurity ion injection region 38 (see FIG. 10). The second silicon layer 42 may be a second strained silicon layer of a recovered impurity type.

In some embodiments, if the first impurity ions 37 (see FIG. 10) are second conductive-type (e.g., N-type) impurities, the second impurity ions 40 may be first conductive-type (e.g., P-type) impurities. In some embodiments, if the first impurity ions 37 (see FIG. 10) are first conductive-type (e.g., P-type) impurities, the second impurity ions 40 may be second conductive-type (e.g., N-type) impurities.

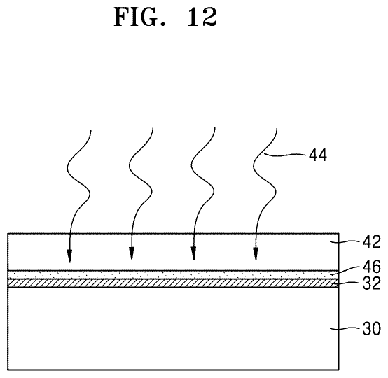

Referring to FIG. 12, heat 44 is applied to the impurity ion injection region 38 (see FIG. 11) and the second silicon layer 42 to activate the impurity ions included in the impurity ion injection region 38 (see FIG. 11).

A thermal process of applying the heat 44 to the impurity ion injection region 38 (see FIG. 11) and the second silicon layer 42 may be performed at a high temperature of about 1000° C. Through this thermal process, a first impurity region 46 may be formed on the insulating layer 32. The first impurity region 46 may be an impurity region of a conductive type opposite to the conductive type of the first silicon layer 30 and the second silicon layer 42. The first impurity region 46 may have a constant doping concentration of impurities in a direction that is perpendicular to the surface of the first silicon layer 30.

Referring to FIG. 13, upon undergoing the process of FIG. 12, the third semiconductor wafer WF3 having the insulating layer 32, the first impurity region 46, and the second silicon layer 42 formed on the first silicon layer 30 may be manufactured. The vertical channel transistor VCT to be described below may be manufactured on the third semiconductor wafer WF3 having the first impurity region 46, i.e., the second silicon layer 42 having the first impurity region 46 formed therebeneath.

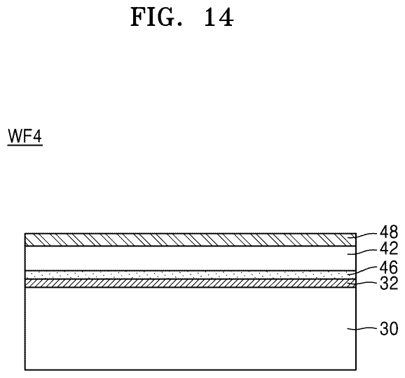

FIG. 14 is a cross-sectional view for describing a method of manufacturing a semiconductor wafer, according to an embodiment.

Particularly, FIG. 14 corresponds to a method of manufacturing a fourth semiconductor wafer WF4 used to manufacture the semiconductor memory device of FIGS. 1 to 3. The manufacturing process of FIGS. 9 to 13 is performed. Then, the insulating layer 32, the first impurity region 46, and the second silicon layer 42 may be formed on the first silicon layer 30.

Thereafter, a second impurity region 48 is formed on the second silicon layer 42. The second impurity region 48 may be formed by injecting impurity ions into the second silicon layer 42 and activating the injected impurity ions like FIGS. 4 and 5. The second impurity region 48 may be an impurity region of a conductive type opposite to the conductive type of the second silicon layer 42.

The second impurity region 48 may have a constant doping concentration of impurities in a direction that is perpendicular to the surface of the second silicon layer 42. The vertical channel transistor VCT may be manufactured on this fourth semiconductor wafer WF4 having the first impurity region 46 and the second impurity region 48.

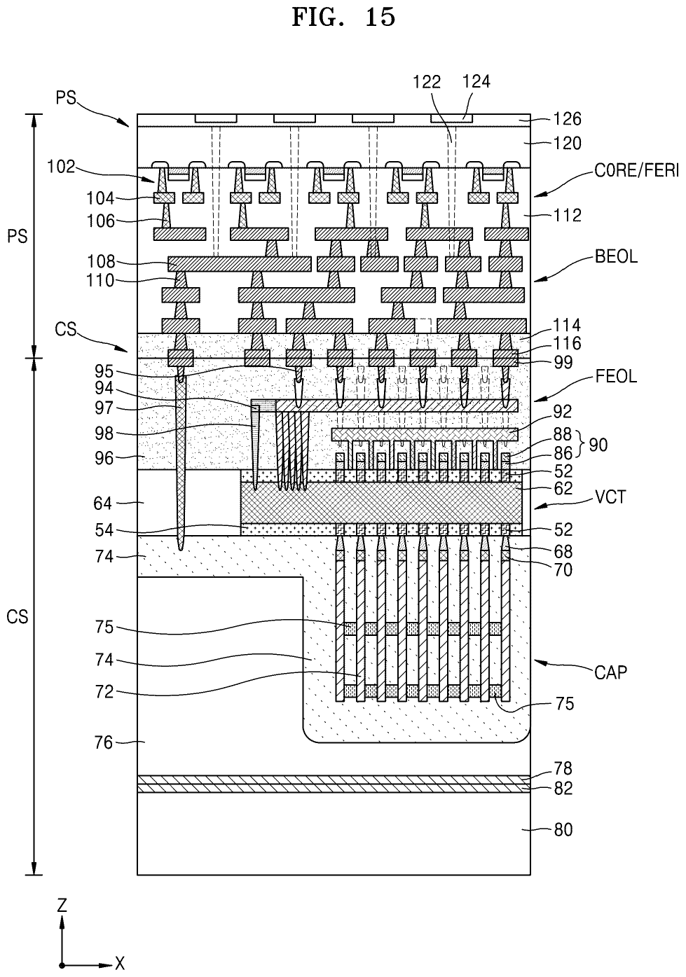

FIG. 15 is a cross-sectional view of a semiconductor memory device according to an embodiment.

Particularly, the semiconductor memory device may include a peripheral circuit structure PS bonded onto a cell array structure CS. The cell array structure CS may include the vertical channel transistor VCT and a first wiring structure FEOL. The cell array structure CS may be shown as a cross-sectional view taken along line C-C′ of FIG. 1.

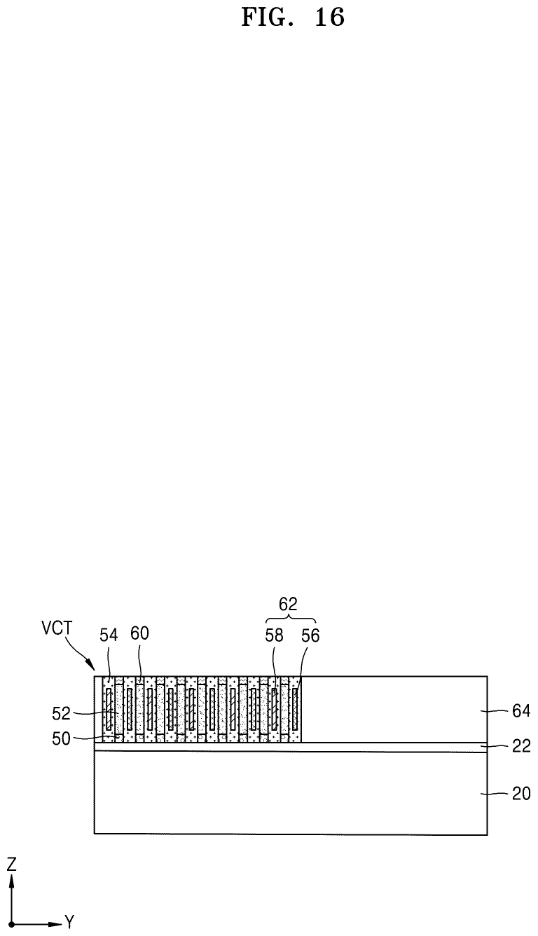

The vertical channel transistor VCT may include active patterns 52, gate electrodes 62, gate insulating patterns 54, and a first insulating layer 64. First source/drain regions 50 (see FIG. 16) and second source/drain regions 60 (see FIG. 16) to be described below may be respectively formed beneath and on the active patterns 52.

The active patterns 52 may correspond to the first and second active patterns AP1 and AP2 of FIGS. 1 to 3. The active patterns 52 are shown at back portions of the gate electrodes 62. The gate insulating patterns 54 may be at opposite sides of the active patterns 52. The gate insulating patterns 54 may have a shape surrounding the active patterns 52 in a plan view.

A capacitor CAP is beneath the vertical channel transistor VCT. The capacitor CAP may include storage electrodes 72, a plate electrode 74, and a capacitor dielectric layer between the storage electrodes 72 and the plate electrode 74. The capacitor dielectric layer is not shown for convenience.

The capacitor CAP may be electrically connected to the active patterns 52 of the vertical channel transistor VCT through contact patterns 68 and landing pads 70. The contact patterns 68 and the landing pads 70 may be in contact with the active patterns 52 of the vertical channel transistor VCT. The contact patterns 68 may correspond to the contact patterns BC of FIGS. 1 to 3 described above.

The capacitor CAP may be connected to the second source/drain regions 60 formed on the active patterns 52, through the contact patterns 68 and the landing pads 70 as described below. The capacitor CAP may correspond to the capacitors CAP of FIG. 1.

In some embodiments, the contact patterns 68 may include a metal pattern without including a dopant source layer (e.g., an impurity-doped polysilicon pattern). When the second source/drain regions 60 are formed on the active patterns 52 in advance, the contact patterns 68 may be formed not of impurity-doped polysilicon but of a metal pattern. In some embodiments, the contact patterns 68 may include a dopant source layer (e.g., an impurity-doped polysilicon pattern).

A second insulating layer 76 sufficiently covering the plate electrode 74 may be formed below the capacitor CAP. A third substrate 80 bonded to the second insulating layer 76 by a second bonding insulating layer 78 and a third bonding insulating layer 82 may be under the second insulating layer 76.

The first wiring structure FEOL may include a gap structure 92, a first wiring layer 94, first to third metal plugs 95, 97, and 98, a first wiring insulating layer 96, and a first bonding pad 99. The first wiring structure FEOL may be connected to the vertical channel transistor VCT through a bit line 90. The bit line 90 may correspond to the bit line BL of FIGS. 1 to 3. The bit line 90 may include a single layer or double layers.

The bit line 90 may be formed of a plurality of metal patterns. In some embodiments, the bit line 90 may be formed of a first metal pattern 86 and a second metal pattern 88. The bit line 90 may be in contact with the first source/drain regions 50 (see FIG. 16) of the vertical channel transistor VCT.

The gap structure 92 may correspond to the gap structures GAS of FIG. 1. The first metal plug 95 may be connected to the first wiring layer 94. The second metal plug 97 may be connected to the first bonding pad 99 and the plate electrode 74 of the capacitor CAP. The third metal plug 98 may be connected to the first wiring layer 94 and a gate electrode 62. The first wiring insulating layer 96 may insulate among the gap structure 92, the first wiring layer 94, the first to third metal plugs 95, 97, and 98, and the first bonding pad 99. The first bonding pad 99 may be formed of copper.

The peripheral circuit structure PS may include a core and peripheral circuit region CORE/FERI and a second wiring structure BEOL beneath the core and peripheral circuit region CORE/FERI. The core and peripheral circuit region CORE/FERI may include core and peripheral circuit transistors 102, an electrode layer 104 and a plug layer 106 electrically connected to the core and peripheral circuit transistors 102, and a second wiring insulating layer 112. The core and peripheral circuit transistors 102 may include row and column decoders, a sense amplifier, and control logics.

The second wiring structure BEOL may include a second wiring layer 108, a fourth metal plug 110, the second wiring insulating layer 112, and a second bonding pad 116. The second bonding pad 116 may be formed in the top layer of the peripheral circuit structure PS. The second bonding pad 116 may be formed of copper.

As described above, in the semiconductor memory device according to the inventive concept, the first source/drain region 50 (see FIG. 16) or both the first and second source/drain regions 50 and 60 (see FIG. 16) is or are previously formed, and thus, it may be unlikely/prevented that the capacitor CAP or the core and peripheral circuit transistors 102 are affected by a high-temperature thermal process.

Accordingly, the semiconductor memory device according to the inventive concept may include the vertical channel transistor VCT capable of improving the integration of the semiconductor memory device and impede/prevent the degradation of the capacitor CAP or the core and peripheral circuit transistors 102.

FIGS. 16 to 24 are cross-sectional views for describing a method of manufacturing the semiconductor memory device of FIG. 15.

Particularly, the semiconductor memory device of FIGS. 16 to 24 may be manufactured using the first semiconductor wafer WF1 or the second semiconductor wafer WF2 prepared above. Alternatively, the semiconductor memory device of FIGS. 16 to 24 may be manufactured using the third or fourth semiconductor wafer WF3 or WF4 prepared above.

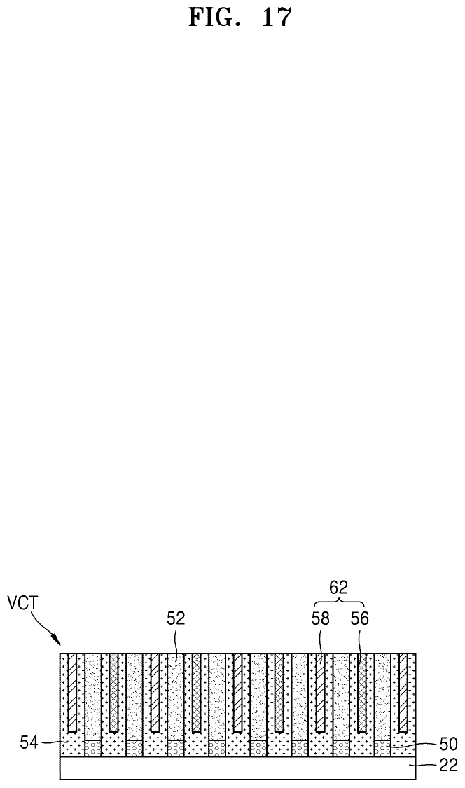

Referring to FIGS. 16 and 17, FIG. 17 is a partial magnified view of FIG. 16. The first semiconductor wafer WF1 or the second semiconductor wafer WF2 may be prepared through the manufacturing process of FIGS. 4 to 8. As described above, the vertical channel transistor VCT is manufactured in/on the first substrate 10 (see FIG. 7 or 8) on the first bonding insulating layer 22 of the first semiconductor wafer WF1 or the second semiconductor wafer WF2.

The vertical channel transistor VCT may include the active patterns 52, the gate electrodes 62, the gate insulating patterns 54, the first source/drain regions 50, the second source/drain regions 60, and the first insulating layer 64. A plurality of active patterns 52 may be formed to be separated from each other in the second horizontal direction (the Y direction) by patterning the first substrate 10 (see FIG. 7 or 8).

When the first substrate 10 (see FIG. 7 or 8) is patterned, the first source/drain regions 50 may be formed beneath the active patterns 52, respectively. The first source/drain regions 50 may be regions formed by patterning the first impurity region 18 of FIG. 7.

When the first substrate 10 (see FIG. 7 or 8) is patterned, the second source/drain regions 60 may be formed on the active patterns 52, respectively. The second source/drain regions 60 may be regions formed by patterning the second impurity region 24 of FIG. 8. A first source/drain region 50 and a second source/drain region 60 may have a constant (or uniform) doping concentration in the vertical direction (the Z direction) that is perpendicular to the second substrate 20. In other words, the first source/drain region 50 and the second source/drain region 60 may have a doping concentration constant (or uniform) without changing in the vertical direction (the Z direction) that is perpendicular to the second substrate 20. In some embodiments, the second source/drain regions 60 may be formed not in the present process but in a subsequent process.

The active patterns 52 may correspond to the first and second active patterns AP1 and AP2 of FIGS. 1 to 3. A plurality of active patterns 52 may be provided that are separated from each other in the first horizontal direction (the X direction) that is perpendicular to the second horizontal direction (the Y direction) as shown in FIG. 1. The first source/drain regions 50 may correspond to the first source/drain regions SDR1 shown in FIGS. 1 to 3. The second source/drain regions 60 may correspond to the second source/drain regions SDR2 shown in FIGS. 1 to 3.

The gate electrodes 62 may be formed between the active patterns 52 in the second horizontal direction (the Y direction). The gate electrodes 62 may include first gate electrodes 56 and second gate electrodes 58. The first gate electrodes 56 may correspond to the first and second word lines WL1 and WL2 of FIGS. 1 to 3. The second gate electrodes 58 may correspond to the back-gate electrodes BG of FIGS. 1 to 3.

The gate insulating patterns 54 may be formed between the active patterns 52 and the gate electrodes 62. The gate insulating patterns 54 may have a shape surrounding the active patterns 52 in a plan view. The gate insulating patterns 54 may correspond to the gate insulating patterns GOX of FIGS. 1 to 3.

The first insulating layer 64 may be formed on the first bonding insulating layer 22 after forming the active patterns 52, the gate electrodes 62, and the gate insulating patterns 54. The first insulating layer 64 may be formed of a silicon oxide layer.

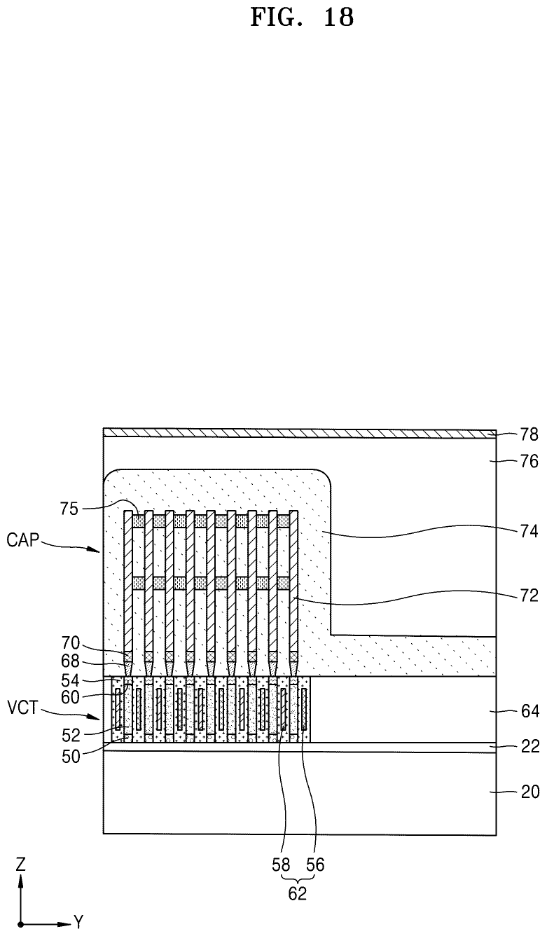

Referring to FIG. 18, the capacitor CAP is formed on the vertical channel transistor VCT. The capacitor CAP electrically connected to the vertical channel transistor VCT through the contact patterns 68 and the landing pads 70 is formed on the active patterns 52 of the vertical channel transistor VCT. In more detail, the capacitor CAP electrically connected to the vertical channel transistor VCT through the contact patterns 68 and the landing pads 70 is formed on the second source/drain regions 60 on the active patterns 52. The capacitor CAP may correspond to the capacitors CAP of FIG. 1.

The contact patterns 68 may correspond to the contact patterns BC of FIGS. 1 to 3. The landing pads 70 may correspond to the landing pads LP of FIGS. 1 to 3. In some embodiments, when the vertical channel transistor VCT is formed using the first semiconductor wafer WF1 described above, the contact patterns 68 may be formed of an impurity-doped polysilicon pattern. After forming the contact patterns 68, the second source/drain regions 60 may be formed through heat treatment.

In some embodiments, when the vertical channel transistor VCT is formed using the second semiconductor wafer WF2 described above, the contact patterns 68 may be formed of a metal pattern. In some embodiments, either the contact patterns 68 or the landing pads 70 may be omitted.

The capacitor CAP may include the storage electrodes 72, the plate electrode 74, and a capacitor dielectric layer (not shown) between the storage electrodes 72 and the plate electrode 74. The storage electrodes 72 may be in contact with the landing pads 70, respectively. A supporter 75 supporting the storage electrodes 72 may be between the storage electrodes 72.

The second insulating layer 76 sufficiently covering the plate electrode 74 may be formed on the capacitor CAP. The second insulating layer 76 may be a silicon oxide layer. The second bonding insulating layer 78 may be formed on the second insulating layer 76. The second bonding insulating layer 78 may be formed of a silicon nitride layer.

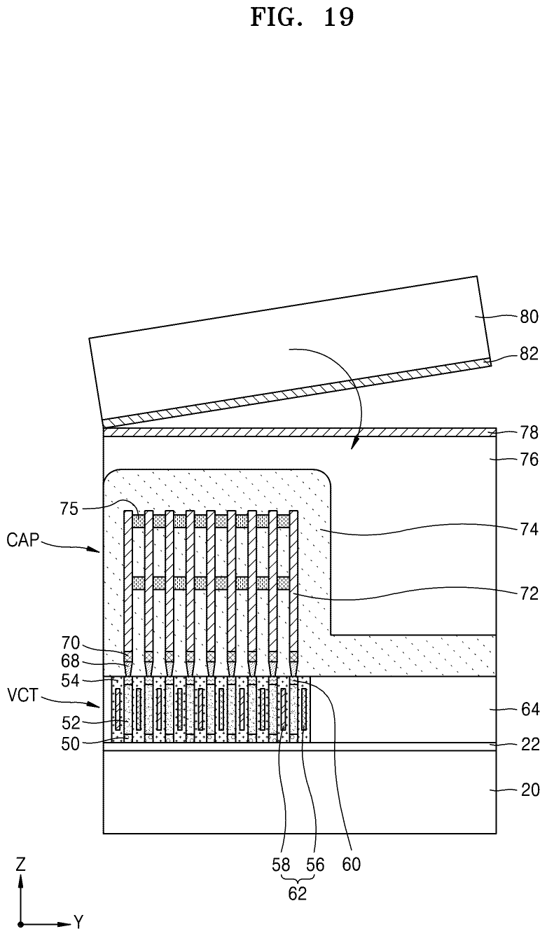

Referring to FIG. 19, the third (or “first”) substrate 80 is prepared. The third substrate 80 may include a silicon substrate. The third bonding insulating layer 82 may be formed on the third substrate 80. The third bonding insulating layer 82 may be formed of a silicon nitride layer. The second bonding insulating layer 78 formed above the capacitor CAP and the vertical channel transistor VCT on the second substrate 20 is bonded to the third bonding insulating layer 82 formed on the third substrate 80. The second bonding insulating layer 78 is in contact with and bonded to the third bonding insulating layer 82.

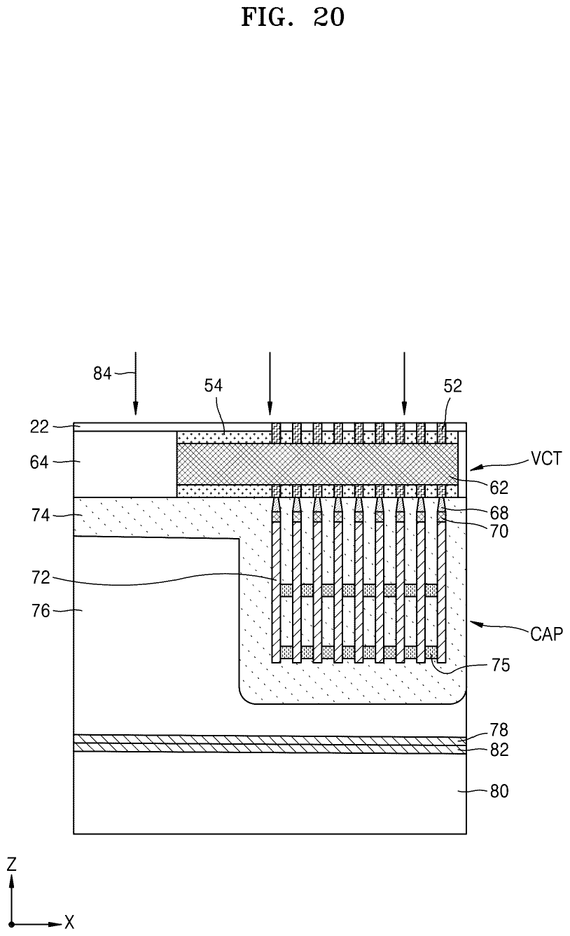

Referring to FIG. 20, the bonded structure described above is upside down such that the third substrate 80 is at the bottom, and then the rear surface of the second substrate 20 is ground through a grinding process 84 by using the first bonding insulating layer 22 as a grinding stop point. By doing this, the second substrate 20 may be removed. Accordingly, the third bonding insulating layer 82, the second bonding insulating layer 78, the capacitor CAP, and the vertical channel transistor VCT may be formed on the third substrate 80.

FIG. 20 shows, to describe a wiring connection relationship described below, the structure of the vertical channel transistor VCT as a cross-section in the first horizontal direction (the X direction) of FIG. 1. Accordingly, in FIG. 20, the gate electrode 62 may extend in the first horizontal direction (the X direction). The active patterns 52 may extend in the vertical direction (the Z direction) and be separated from each other in the first horizontal direction (the X direction). For convenience, the first source/drain regions 50 and the second source/drain regions 60 formed on and beneath the active patterns 52 are not shown.

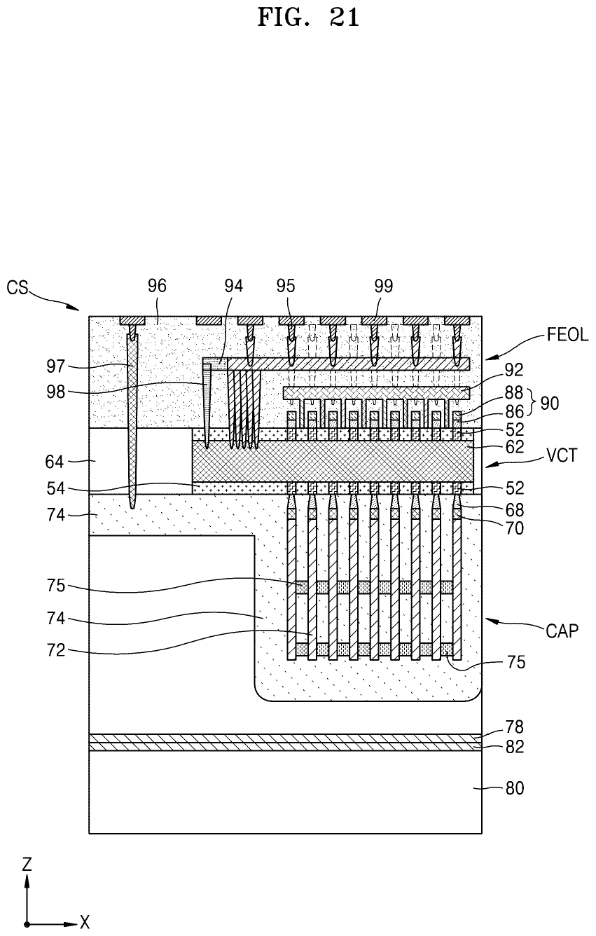

Referring to FIG. 21, the cell array structure CS is manufactured by forming the first wiring structure FEOL electrically connected to the vertical channel transistor VCT through the bit line 90. The cell array structure CS may be shown as a cross-sectional view taken along line C-C′ of FIG. 1. The bit line 90 may correspond to the bit line BL of FIGS. 1 to 3. The bit line 90 may be formed of a plurality of metal patterns. In some embodiments, the bit line 90 may be formed of the first metal pattern 86 and the second metal pattern 88.

The bit line 90 may be electrically connected to the active patterns 52 of the vertical channel transistor VCT. The bit line 90 may be in contact with the first source/drain regions 50 (see FIG. 16) of the vertical channel transistor VCT. The first wiring structure FEOL may be formed on the bit line 90. The first wiring structure FEOL may include the gap structure 92, the first wiring layer 94, the first to third metal plugs 95, 97, and 98, the first wiring insulating layer 96, and the first bonding pad 99. The first bonding pad 99 may be formed of copper.

The gap structure 92 may correspond to the gap structures GAS of FIG. 1. The first metal plug 95 may be electrically connected to the first wiring layer 94. The second metal plug 97 may be electrically connected to the first bonding pad 99 and the plate electrode 74 of the capacitor CAP. The third metal plug 98 may be electrically connected to the first wiring layer 94 and the gate electrode 62. The first wiring insulating layer 96 may insulate among the gap structure 92, the first wiring layer 94, the first to third metal plugs 95, 97, and 98, and the first bonding pad 99.

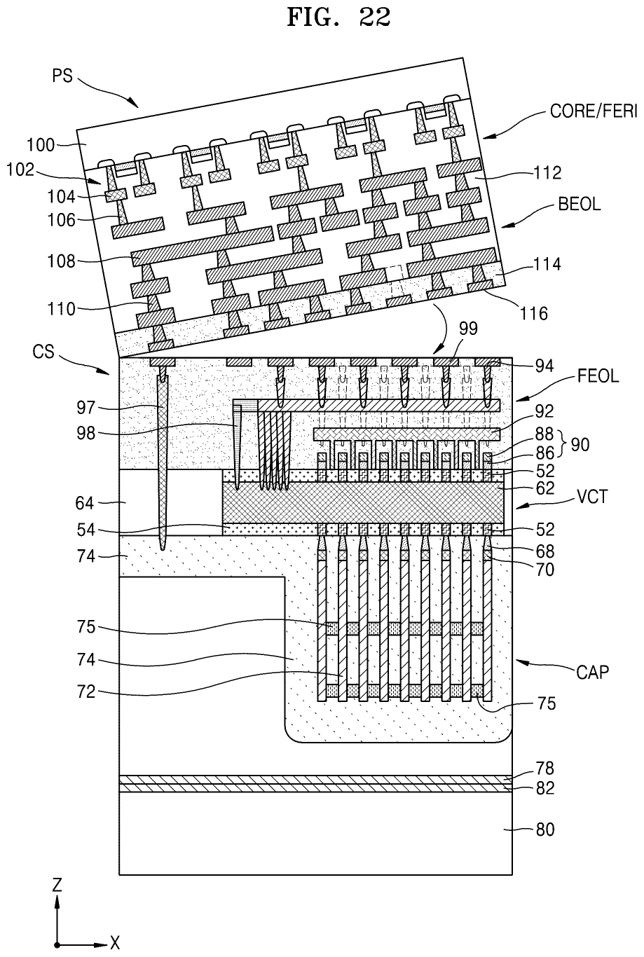

Referring to FIG. 22, the peripheral circuit structure PS is prepared. The peripheral circuit structure PS may include the core and peripheral circuit region CORE/FERI formed on a third substrate 100 and the second wiring structure BEOL formed on the core and peripheral circuit region CORE/FERI.

The core and peripheral circuit region CORE/FERI may include the core and peripheral circuit transistors 102 formed on the third substrate 100, the electrode layer 104 and the plug layer 106 electrically connected to the core and peripheral circuit transistors 102, and the second wiring insulating layer 112. The core and peripheral circuit transistors 102 may include row and column decoders, a sense amplifier, and control logics.

The second wiring structure BEOL connected to the core and peripheral circuit region CORE/FERI through the electrode layer 104 and the plug layer 106 may be on the core and peripheral circuit region CORE/FERI. The second wiring structure BEOL may include the second wiring layer 108, the fourth metal plug 110, the second wiring insulating layer 112, and the second bonding pad 116. The second bonding pad 116 may be formed in the top layer of the peripheral circuit structure PS. The second bonding pad 116 may be formed of copper.

The peripheral circuit structure PS is bonded onto the cell array structure CS. The first bonding pad 99 of the cell array structure CS is bonded to the second bonding pad 116 of the peripheral circuit structure PS.

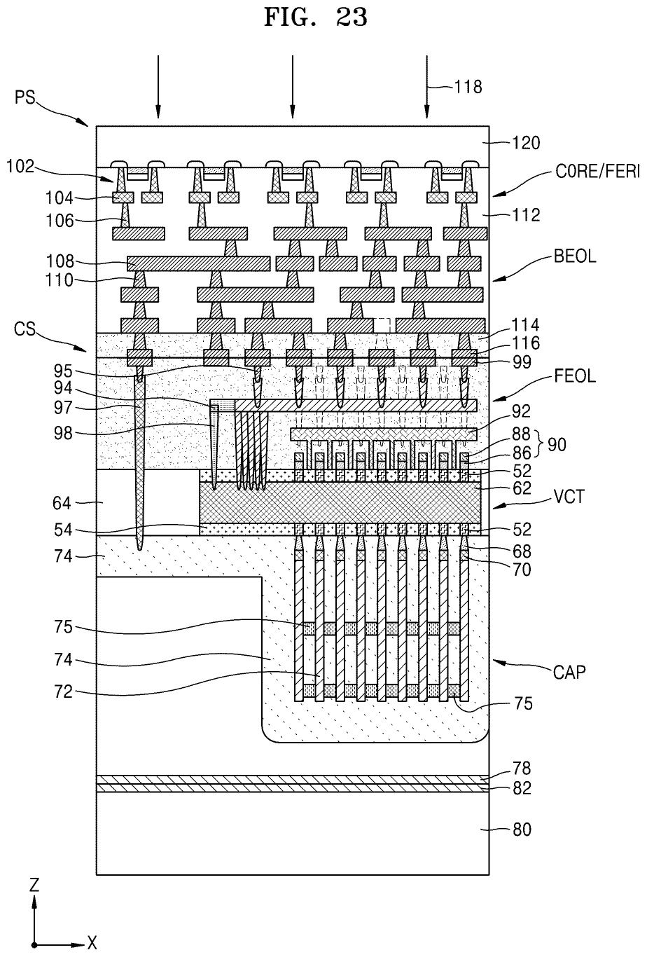

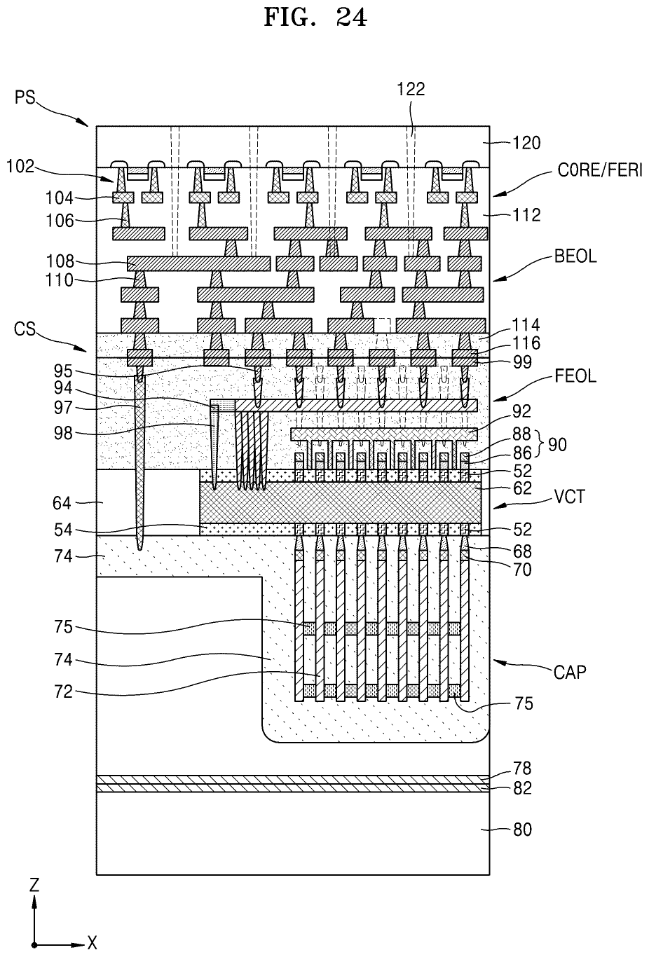

Referring to FIGS. 23 and 24, the rear surface of the third substrate 100 of the peripheral circuit structure PS is ground using a grinding process 118. Accordingly, the third substrate 100 may become a third (or “second”) substrate 120 with a reduced thickness. As shown in FIG. 24, a through via 122 electrically connected to the second wiring layer 108 of the second wiring structure BEOL by penetrating the third substrate 120 is formed. The through via 122 may be a silicon via.

Thereafter, as shown in FIG. 15, the semiconductor memory device is completed by forming, on the third substrate 120, an input/output pad 124 electrically connected to the through via 122 and a pad insulating layer 126 insulating the input/output pad 124.

While the inventive concept has been particularly shown and described with reference to embodiments thereof, it will be understood that various changes in form and details may be made therein without departing from the scope of the following claims.

1. A semiconductor memory device comprising:
a bit line extending above a substrate in a second horizontal direction;
first and second active patterns beneath the bit line, each of the first and second active patterns having a first surface in contact with the bit line without a dopant source layer therebetween and a second surface opposite to the first surface in a vertical direction that is perpendicular to the substrate;
a back-gate electrode between the first and second active patterns and extending above the substrate in a first horizontal direction that is perpendicular to the second horizontal direction by crossing the bit line;
a first word line extending in the first horizontal direction at one side of the first active pattern;
a second word line extending in the first horizontal direction at an opposite side of the second active pattern; and
contact patterns in contact with the second surfaces of the first and second active patterns,
wherein the first and second active patterns comprise first source/drain regions adjacent to the bit line, second source/drain regions adjacent to the contact patterns, and channel regions between the first source/drain regions and the second source/drain regions.

2. The semiconductor memory device of claim 1, wherein the first source/drain regions have a constant doping concentration in the vertical direction that is perpendicular to the substrate.

3. The semiconductor memory device of claim 1, wherein the first and second active patterns include a monocrystalline semiconductor material.

4. The semiconductor memory device of claim 1, wherein each of the first and second active patterns has a width greater than a width of the bit line in the first horizontal direction.

5. The semiconductor memory device of claim 1,
wherein each of the first and second active patterns has a uniform width in the second horizontal direction, and
wherein each of the contact patterns is wider in the second horizontal direction than the uniform width.

6. The semiconductor memory device of claim 1, wherein each of the first and second word lines and the back-gate electrode has an upper surface close to the bit line and a lower surface close to the contact patterns, and the lower surfaces of the first and second word lines are at a different level from a level of the lower surface of the back-gate electrode.

7. The semiconductor memory device of claim 1, wherein each of the first and second word lines and the back-gate electrode has a length in the vertical direction, and the lengths of the first and second word lines are different from the length of the back-gate electrode.

8. The semiconductor memory device of claim 1, further comprising gate insulating patterns between the first and second active patterns and the first and second word lines.

9. The semiconductor memory device of claim 8, further comprising a second insulating pattern between the first and second word lines and between the gate insulating patterns.

10. The semiconductor memory device of claim 1, further comprising a first insulating pattern between the first and second active patterns adjacent to each other in the second horizontal direction and between the second source/drain regions.

11. A semiconductor memory device comprising:
a bit line extending above a substrate in a second horizontal direction;
first and second active patterns alternating with each other in the second horizontal direction beneath the bit line, each of the first and second active patterns having a first surface in contact with the bit line without a dopant source layer therebetween and a second surface opposite to the first surface in a vertical direction that is perpendicular to the substrate;
a back-gate electrode between the first and second active patterns and extending above the substrate in a first horizontal direction that is perpendicular to the second horizontal direction by crossing the bit line;
a first word line extending in the first horizontal direction at one side of the first active pattern;
a second word line extending in the first horizontal direction at an opposite side of the second active pattern;
gate insulating patterns between the first and second active patterns and the first and second word lines; and
contact patterns in contact with the second surfaces of the first and second active patterns without a dopant source layer therebetween,
wherein the first and second active patterns comprise first source/drain regions adjacent to the bit line, second source/drain regions adjacent to the contact patterns, and channel regions between the first source/drain regions and the second source/drain regions.

12. The semiconductor memory device of claim 11, wherein the first source/drain regions have a constant doping concentration in the vertical direction that is perpendicular to the substrate.

13. The semiconductor memory device of claim 11, wherein the second source/drain regions have a constant doping concentration in the vertical direction that is perpendicular to the substrate.

14. The semiconductor memory device of claim 11,
wherein each of the first and second active patterns have a first side surface and a second side surface opposite to each other in the second horizontal direction,
wherein the first word line is adjacent to the first side surface, and
wherein the second word line is adjacent to the second side surface.

15. The semiconductor memory device of claim 11, further comprising a capacitor on the contact patterns.

16. A semiconductor memory device comprising:
a cell array structure on a first substrate; and
a peripheral circuit structure bonded to the cell array structure,
wherein the cell array structure comprises:
a capacitor on the first substrate;
a vertical channel transistor above the capacitor and electrically connected to the capacitor through contact patterns; and
a first wiring structure above the vertical channel transistor and electrically connected to the vertical channel transistor through a bit line,
wherein the vertical channel transistor comprises:
active patterns located above the first substrate in a vertical direction and separated from each other in a first horizontal direction and a second horizontal direction; and
first source/drain regions and second source/drain regions on and beneath the active patterns, respectively, the first source/drain regions being in contact with and electrically connected to the bit line without a dopant source layer therebetween, and the second source/drain regions being electrically connected to the capacitor through the contact patterns in contact with the second source/drain regions without a dopant source layer therebetween, and
wherein the peripheral circuit structure comprises:
a peripheral circuit transistor beneath a second substrate; and
a second wiring structure beneath the peripheral circuit transistor and bonded to the first wiring structure.

17. (canceled)

18. The semiconductor memory device of claim 16, wherein the second source/drain regions have a constant doping concentration in the vertical direction that is perpendicular to the first substrate.

19. The semiconductor memory device of claim 16, further comprising:
a first bonding insulating layer on the first substrate; and
a second bonding insulating layer beneath the capacitor,
wherein the first bonding insulating layer is bonded to the second bonding insulating layer.

20. The semiconductor memory device of claim 16, wherein the cell array structure further comprises a first bonding pad, the peripheral circuit structure further comprises a second bonding pad opposite to the first bonding pad, and the first bonding pad is bonded to the second bonding pad.

21. The semiconductor memory device of claim 16, wherein the peripheral circuit structure further comprises:
a through via electrically connected to the second wiring structure on the second substrate; and
an input/output pad electrically connected to the through via.
